(19) United States
(12) Patent Application Publication
(10) Pub. No.: US 2023/0011361 A1
(43) Pub. Date: Jan. 12, 2023

(54) SYSTEM AND METHOD FOR WAFER BREAKAGE PREVENTION

(71) Applicant: CHANGXIN MEMORY TECHNOLOGIES, INC., Hefei (CN)

(72) Inventor: Fencheng ZHENG, Hefei City (CN)

(21) Appl. No.: 17/455,978

(22) Filed: Nov. 22, 2021

Related U.S. Application Data
(63) Continuation of application No. PCT/CN2021/107907, filed on Jul. 22, 2021.

(30) Foreign Application Priority Data
Jul. 7, 2021 (CN) 202110766341.X

(51) Int. Cl. H01L 21/687; H01L 21/683; H01L 21/67

(52) U.S. Cl. CPC H01L 21/68742; H01L 21/6833; H01L 21/67242

(57) ABSTRACT

The present application discloses a pressure drive system and method, and a semiconductor manufacture apparatus employing the system to perform pressure drive; by importing information of this wafer before a manufacture process initiates, a corresponding safe driving pressure and a corresponding safety threshold for each wafer are acquired and set for pressure control, and an abnormality judgment is performed based on data fed back by a pressure detection module in real time, thereby effectively avoiding a wafer breakage caused when an electrostatic release is abnormal, and the pressures for various wafers under different situations are controllable, and thus, an accuracy of the control is improved; with real-time feedback from the pressure detection module and a pressure regulation module, a wafer breakage, caused when an electrostatic release is abnormal, is effectively avoided.

### CROSS REFERENCE TO RELATED APPLICATIONS

This application is a continuation application of International Patent Application No. PCT/CN2021/107907, filed on Jul. 22, 2021, which claims priority to Chinese Patent Application No. 202110766341.X, filed with the Chinese Patent Office on Jul. 7, 2021 and entitled “SYSTEM AND METHOD FOR WAFER BREAKAGE PREVENTION”. International Patent Application No. PCT/CN2021/107907 and Chinese Patent Application No. 202110766341.X are incorporated herein by reference in their entireties.

### TECHNICAL FILED

The present application relates to the field of semiconductor production, in particular to a system and method for wafer breakage prevention.

### BACKGROUND

An advanced manufacture apparatus for etching a semiconductor usually uses an inert gas for conduction of temperature between an electrostatic chuck and a wafer. In order to avoid a shift of the wafer, a DC voltage is applied to the electrostatic chuck, so as to generate an electrostatic force to adsorb the wafer. The electrostatic force is to be released before a manufacture process ends, and a lift pin is then employed to lift up the wafer for a subsequent transmission. The electrostatic force is required to be released before the manufacture process ends; however, as the production and manufacture proceeds, an error may inevitably occur for the release of the electrostatic force, and there exist differences among wafers or process chambers, such that a breakage of the wafer caused by the lift pin happens occasionally, which reduces a wafer manufacture yield and increases a production cost.

FIGS. 1 to 3 illustrate statuses of a wafer manufacture process, and a wafer 1 is adsorbed via an electrostatic force which is generated by an electrostatic chuck 2. FIG. 1 illustrates that in the wafer manufacture process, a DC voltage is applied to the electrostatic chuck 2, so as to generate the electrostatic force to adsorb the wafer 1; FIG. 2 is a schematic diagram illustrating that the electrostatic force is released before the manufacture process ends, and then a lift pin 3 is employed to lift the wafer 1, and the wafer manufacture process ends normally; FIG. 3 is a schematic diagram illustrating that in the process of lifting the wafer 1 by the lift pin 3, an error occurs for the release of the electrostatic force, such that the lift pin 3 causes a breakage of the wafer 1.

Therefore, how to solve the above issue becomes a problem required to be promptly solved by a person skilled in the art.

### SUMMARY

According to some embodiments, a first aspect of the present application provides a pressure drive system for providing a driving pressure for a wafer lifting device in a semiconductor manufacture apparatus, the pressure drive system including:

a pressure detection module connected to a pressure output terminal of the lifting device is configured to detect and send a lifting pressure of the lifting device to a pressure control module;

a pressure regulation module connected to a pressure input terminal of the lifting device is configured to regulate the driving pressure for the lifting device based on a driving pressure signal sent by the pressure control module; and

the pressure control module is configured to generate the driving pressure signal for a current wafer based on the received lifting pressure and send the driving pressure signal to the pressure regulation module.

According to some embodiments, a second aspect of the present application also provides a pressure drive method, including the steps of:

detecting a lifting pressure of a lifting device; and

generating a driving pressure signal for a current wafer based on the received lifting pressure, and regulating a driving pressure for the lifting device based on the driving pressure signal, and then correcting the lifting pressure output by the lifting device.

According to some embodiments, a third aspect of the present application further provides a semiconductor manufacture apparatus, including a lifting device, an electrostatic adsorption device, and the pressure drive system as described according to the first aspect of the present application, wherein

the electrostatic adsorption device, on which a wafer is placed, is configured to generate an adsorption force to adsorb the wafer during a manufacture process;

the lifting device is located underneath the electrostatic adsorption device and includes a lift pin, and when the manufacture process ends, the lifting device generates a lifting pressure to lift the wafer by the lift pin from the electrostatic adsorption device; and

the pressure drive system is connected to the lifting device and configured to detect the lifting pressure of the lifting device and generate the driving pressure signal for the current wafer based on the lifting pressure, so as to regulate the driving pressure for the lifting device.

### BRIEF DESCRIPTION OF DRAWINGS

FIG. 1 is a schematic diagram of a wafer adsorbed via an electrostatic force which is generated by an electrostatic chuck;

FIG. 2 is a schematic diagram of a normal ending of a manufacture process while a lift pin lifts the wafer;

FIG. 3 is a schematic diagram of a breakage of the wafer caused when the lift pin lifts the wafer;

FIG. 4 is a schematic diagram of a Johnsen-Rahbek type of electrostatic chuck;

FIG. 5 is a schematic diagram of a Coulombic-type of electrostatic chuck;

FIG. 6 is a composition block diagram of a system for wafer breakage prevention according to the present application;

FIG. 7 is a composition block diagram of a pressure control module according to the present application;

FIG. 8 is a flow diagram of a method for wafer breakage prevention according to the present application; and

FIG. 9 is a schematic structural diagram of a lifting device according to the present application.

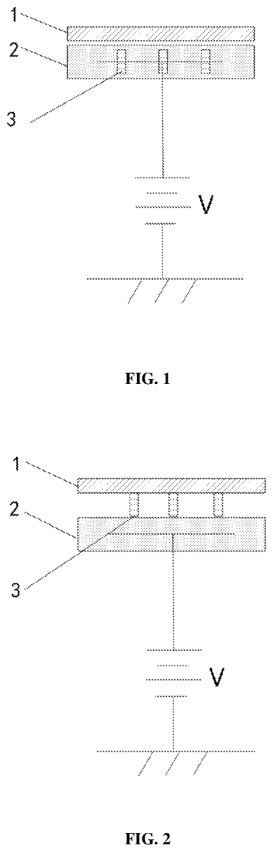

### DESCRIPTION OF EMBODIMENTS

Two types of electrostatic chucks which are commonly used in semiconductor manufacture are a Johnsen-Rahbek (referred to as “JR” for short hereinafter) type and a Coulombic-type (referred to as “CB” for short hereinafter).

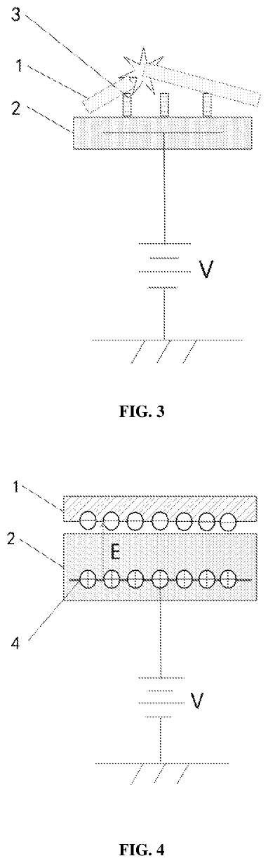

The JR type of electrostatic chuck as shown in FIG. 4 illustrates an internal electrode 4. Since an insulation layer of the electrostatic chuck 2 is doped, electrons gather on a top end of the electrostatic chuck 2 due to an effect of an electrostatic force. An advantage of this type of electrostatic chuck is a high adsorption force, and only a low adsorption voltage is required; a disadvantage is that the release of the electrons on the top end are difficult, and the electrostatic force cannot be entirely released, and thus, the wafer 1 is likely to be broken when the lift pin is lifting the wafer 1.

The CB type of electrostatic chuck as shown in FIG. 5 illustrates the internal electrode 4. The movements of the electrons are difficult due to a high resistance of the insulation layer, and the electrons would not gather on the top end of the electrostatic chuck 2. However, in long term production processes, polymers are adsorbed onto the electrostatic chuck 2, causing electrons' gathering and incomplete release of the electrostatic force, and thus, the wafer 1 is likely to be broken when the lift pin is lifting the wafer 1.

By using a big data technology, the present application acquires a safety threshold and a safe driving pressure for a current wafer by importing information of this wafer to cloud before the manufacture process initiates, preventing the lift pin from damaging the wafer when the electrostatic release is abnormal, and increasing the wafer manufacture yield. Detailed illustration of embodiments of the present application is provided below in combination with the accompanying drawings.

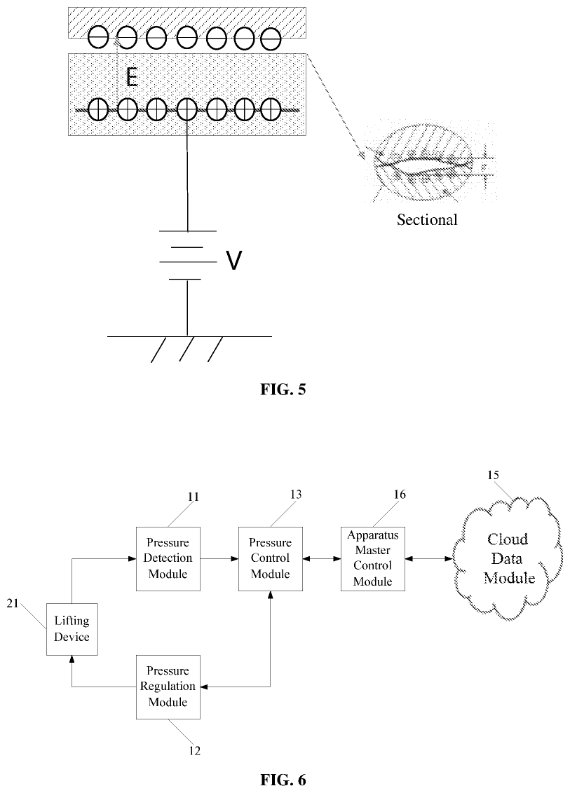

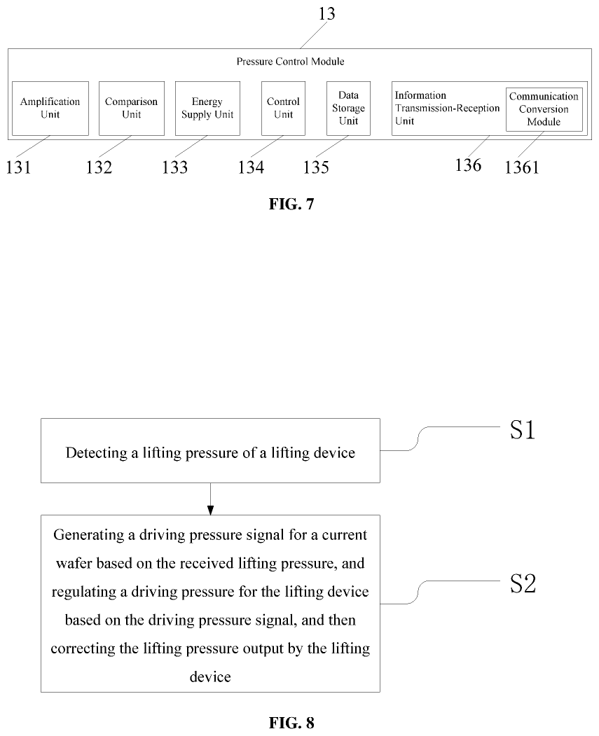

A first embodiment of the present application provides a pressure drive system, of which a composition block diagram is as shown in FIG. 6; the pressure drive system includes a pressure detection module 11, a pressure regulation module 12, a pressure control module 13, and a cloud data module 15, wherein the pressure detection module 11, the pressure regulation module 12, and the pressure control module 13 are successively connected, and the pressure control module 13 is connected to an apparatus master control module 16 and a cloud data module 15 via a communication conversion module 1361 of the pressure control module 13. The pressure detection module 11 is connected to a pressure output terminal of the lifting device 21 and configured to detect and send a lifting pressure of the lifting device 21 to the pressure control module 13. The pressure detection module 11 may employ a piezoelectric transducer to measure a lifting force. The piezoelectric transducer is a piezoelectric effect based transducer, and is a self power generation and electro-mechanical conversion transducer. Sensitive elements of the piezoelectric transducer are made of piezoelectric materials. The surface of the piezoelectric material generates electric charge after being subjected to a force. After amplification and impedance change through a charge amplifier and a measuring circuit, the electric charge becomes an output of the quantity of the electric charge which is in direct proportion to the subjected external force. The piezoelectric transducer may be of traditional polycrystalline piezoceramic materials, e.g., polyvinylidene fluoride (PVDF) piezoelectric film, which is thinner, has a higher piezoelectric constant, and is easier to be machined, as compared to traditional piezoceramics.

The pressure regulation module 12 is connected to a pressure input terminal of the lifting device 21 and configured to regulate the driving pressure for the lifting device 21 based on a driving pressure signal sent by the pressure control module 13. The pressure regulation module 12 accepts control from the pressure control module 13, enables an automatic pressure regulation, and has a function of dual ends pressure detection and feedback. The pressure regulation module 12 regulates the driving pressure signal for the lifting device 21 based on a pressure control signal output by the pressure control module 13, and feedbacks an actual driving pressure signal to the pressure control module 13. For example, an electronic pressure control device (UPC) is used as the pressure regulation module 12, and the UPC is of a high-precision pressure regulation capability and a good stability. The pressure regulation module 12 also feedbacks the actual driving pressure signal to the pressure control module 13. An abnormality judgment is made by the pressure control module 13 based on the received lifting pressure and the actual driving pressure signal.

The pressure control module 13 is configured to generate the driving pressure signal for a current wafer based on the received lifting pressure and send the driving pressure signal to the pressure regulation module 12. The pressure control module 13 generates the driving pressure signal for the current wafer based on the driving pressure and safety threshold corresponding to the current wafer, such that the lifting pressure output by the lifting device 21 matches the driving pressure and safety threshold corresponding to the current wafer. The pressure control module 13 receives the lifting pressure collected by the pressure detection module 11 and the actual driving pressure signal fed back from the pressure regulation module 12, and send data for the entire lifting process to the apparatus master control module 16 via the communication conversion module 1361. The date includes the lifting pressure and the actual driving pressure signal, and also includes a type of the wafer corresponding to the lifting process, a number of use times, a type and thickness of the film, a stress of the wafer, a current phase of the manufacture process and other data.

Specifically, the pressure control module 13 further includes: an amplification unit 131, a comparison unit 132, an energy supply unit 133, a control unit 134, a data storage unit 135, and an information transmission-reception unit 136. FIG. 7 illustrates a composition block diagram of the pressure control module. The detailed illustration of the units described above is provided below in combination with FIG. 7.

The amplification unit 131 is configured to amplify the received lifting pressure. In the case where a PVDF piezoelectric film is used as the pressure detection module 11, since a change in electric charge of the PVDF film cannot be measured directly, the amplification unit 131 is provided to amplify an electric charge signal output by the piezoelectric transducer.

One input terminal of the comparison unit 132 is connected to an output terminal of the amplification unit 131, and the other input terminal is connected to the safety threshold, so as to compare the amplified lifting pressure to the safety threshold. In the case where the amplified lifting pressure is greater than the safety threshold, a state abnormality signal is output.

The energy supply unit 133 is configured to provide electric energy for the pressure detection module 11 and the pressure regulation module 12.

The control unit 134 is configured to control the pressure regulation module 12.

The data storage unit 135 is configured to store data.

The information transmission-reception unit 136 is configured to receive and send data from and to the apparatus master control module 16 via the communication conversion module 1361.

The communication conversion module 1361 is configured for communication conversion between different devices and the pressure control module 13.

The cloud data module 15 collects the information of a wafer and a historical driving pressure and a safety threshold which are corresponding to the wafer, based on these data, calculates the driving pressure and the safety threshold which are corresponding to the current wafer, and outputs them to the pressure control module 13. The information of the wafer includes: a type of the wafer, a number of use times, a type and thickness of the film, a stress of the wafer, a current phase of the manufacture process and other data. The cloud data module 15 collects and learns a data sample for each lifting process, so as to improve an accuracy of the safety threshold of wafer lifting forces for different states of wafers and apparatuses. The safe driving pressure is related to a type of the wafer, a number of use times, a type and thickness of the film, a stress of the wafer, and a current phase of the manufacture process. The safety threshold is less than a minimum of the driving pressure which causes damage to the wafer.

Before the wafer manufacture process initiates, the cloud data module 15 acquires the safety threshold and the safe driving pressure for the current wafer based on the information of the wafer, and sends them to the pressure control module 13; the pressure control module 13 sends the pressure control signal to the pressure regulation module 12 based on the safety threshold and the safe driving pressure, and judges an abnormality in combination with the received lifting pressure and the actual driving pressure signal. The abnormality judgment may specifically include: judging whether a state of the wafer is abnormal based on the received lifting pressure; and judging whether a pressure is abnormal based on the received actual driving pressure signal. For example, whether the state of the wafer is abnormal may be judged through a sudden increase or decrease in a value of the signal such as the obtained lifting pressure, or the actual driving pressure.

According to a second embodiment of the present application, a pressure drive method is provided. The method utilizes the system of the first embodiment of the present application. The flow diagram of the method is as shown in FIG. 8, including the following steps:

detecting and sending, by the pressure detection module 11, a lifting pressure of the lifting device 21 to the pressure control module 13;

generating, by the pressure control module 13 based on the received lifting pressure, a driving pressure signal for the current wafer, and sending, by the pressure control module 13, the driving pressure signal to the pressure regulation module 12; and

regulating, by the pressure regulation module 12 based on the driving pressure signal sent by the pressure control module 13, a driving pressure for the lifting device 21.

The safety threshold and the safe driving pressure for the current wafer are acquired based on the information of the wafer before the wafer manufacture process initiates. The information of the wafer includes: a type of the wafer, a number of use times, a type and thickness of the film, a stress of the wafer, a current phase of the manufacture process or the like. The safety threshold and the safe driving pressure for the wafer correspond to the above information of the wafer and are obtained by the cloud data module taking the data collected for the entire lifting process in each manufacture process as a sample and learning the samples.

During the manufacture process, the lifting device in the semiconductor manufacture apparatus is controllable based on the safety threshold and the safe driving pressure. During the manufacture process, the learned safety threshold and the learned safe driving pressure are used to control the driving pressure for the lifting device, so as to prevent the breakage of the wafer caused when the electrostatic release is abnormal.

The lifting pressure of the lifting device and an actual driving pressure signal are collected in real time, and the abnormality judgment is made in combination with the safety threshold and the collected lifting pressure and the collected actual driving pressure signal.

In the case where the occurrence of an abnormality is asserted, the state abnormality signal is output.

The steps above may be implemented by the various modules according to the first embodiment of the present application.

According to a third embodiment of the present application, a semiconductor manufacture apparatus is provided. The semiconductor manufacture apparatus includes a lifting device, an electrostatic adsorption device, and the pressure drive system as described according to the first aspect of the present application. The electrostatic adsorption device, on which a wafer is placed, is configured to generate an adsorption force to adsorb the wafer during a manufacture process. The electrostatic adsorption device may adopt existing electrostatic adsorption devices in the prior art. The lifting device is located underneath the electrostatic adsorption device, and may be implemented by using a pneumatic lifting device, for example. In this embodiment, a single cavity cylinder is employed to implement the pneumatic lifting device. The lifting device includes a lift pin, and when the manufacture process ends, the lifting device generates a lifting pressure to lift the wafer by the lift pin from the electrostatic adsorption device.

The pressure drive system is connected to the lifting device and configured to detect the lifting pressure of the lifting device and generate the driving pressure signal for the current wafer based on the lifting pressure, so as to regulate the driving pressure for the lifting device.

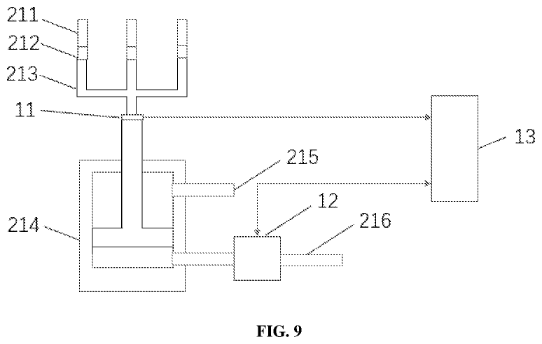

FIG. 9 illustrates a schematic composition diagram of the lifting device according to this embodiment. As shown in FIG. 9, a single cavity cylinder 214 for providing the driving pressure of lifting the wafer includes a first air inlet 215 and a second air inlet 216; the single cavity cylinder 214 is connected to a claw drive 213 via a lifting poker; the claw drive 213 is connected with a lift pin 211 via a bellows 212 to transfer the driving pressure generated by the single cavity cylinder 214 to the lift pin 211; the first air inlet 215 provides a pressure to push the lifting poker downwards, so as to retract the lift pin 211 back in place; the second air inlet 216 is used to push the lifting poker upwards to lift the claw drive 213, and further, the lift pin 211, so as to lift the wafer. An air intake stage is required to intake air when moving the lift pin 211 upwardly to lift the wafer, the magnitude of the pressure is fed back by the pressure control signal, which is output by the pressure control module 13, to the pressure regulation module 12 for pressure regulation. Since the lift pin 211 has influence on the wafer mainly in the lifting process, it should be focused on the control of the air intake condition at the second air inlet 216. The first air inlet 215 is mainly used for lowering the lift pin back in place, and a precise control of the magnitude of the pressure is not necessary as long as the pressure at the first air inlet 215 is guaranteed less than the pressure at the second air inlet 216 when the lift pin is rising and in contrast, the pressure at the first air inlet 215 is guaranteed greater than the pressure at the second air inlet 216 when the lift pin is falling back in place.

The system according to the first embodiment of the present application is connected to the lifting device to prevent the lift pin 211 from damaging the wafer due to the electrostatic release abnormality occurred in the lifting process, and the pressure detection module 11 of the system is connected at the lifting poker of the single cavity cylinder 214 to collect and send the lifting pressure to the pressure control module 13 for process. The pressure regulation module 12 of the system is also connected to the lifting device 21, and controls the lifting device 21 based on the pressure control signal output by the pressure control module 13, and feedbacks the actual driving pressure signal to the pressure control module 13 in real time.

To sum up, the present application provides a pressure drive system and method, and a semiconductor manufacture apparatus employing the system to prevent a wafer breakage; by using the big data technology, the present application imports information of this wafer before the manufacture process initiates so as to acquire and set a corresponding safe driving pressure and a corresponding safety threshold for each wafer, and perform an abnormality judgment based on data fed back by a pressure detection module in real time, thereby effectively avoiding a wafer breakage caused when an electrostatic release is abnormal; and at the end of each manufacture process, the data for that manufacture process is collected to improve reliability of algorithms and increase accuracy of predicted values. The technical solution according to the present application, by importing the information of a wafer involved in a current manufacture process before the manufacture process initiates, acquires and sets a corresponding safe driving pressure and a corresponding safety threshold for each wafer, and controls pressures for various wafers under different situations, and thus, an accuracy of the control is improved; the technical solution timely acquires feedback information via real-time feedback from the pressure detection module and a pressure regulation module, and thus, effectively avoids a wafer breakage caused when an electrostatic release is abnormal, and the technical solution is highly time effective; the technical solution feedbacks to a cloud data module the data for a lifting process in each manufacture process, and with continuous collection of data, improves reliability of algorithms and increases accuracy of predicted values; the system according to the present application is an universal system, and thus, not limited to a particular manufacturer or model, and applicable to a majority of the wafer lifting devices.

Although the present application has been disclosed as above in various embodiments, the present application should not be limited by those embodiments. Those skilled in the art may make changes or modifications to the present application based on the methods and technical solutions disclosed above without departing from the spirit and scope of the present application. Therefore, any simple alterations, equivalent changes and modifications made to the foregoing embodiments based on the technical essence of the present application without departing from the technical solutions proposed in the present application are deemed to fall within the protection scope of the technical solutions in the present application.

What is claimed is:

1. A pressure drive system for providing a driving pressure for a wafer lifting device in a semiconductor manufacture apparatus, the pressure drive system comprising:
a pressure detection module connected to a pressure output terminal of the wafer lifting device being configured to detect and send a lifting pressure of the wafer lifting device to a pressure control module;
a pressure regulation module connected to a pressure input terminal of the wafer lifting device being configured to regulate the driving pressure for the wafer lifting device based on a driving pressure signal sent by the pressure control module; and
the pressure control module being configured to generate the driving pressure signal for a current wafer based on the received lifting pressure and sending the driving pressure signal to the pressure regulation module.

2. The system according to claim 1, further comprising:
a cloud data module for collecting information of a wafer and a historical driving pressure and a safety threshold which are corresponding to the wafer, based on these data, calculating the driving pressure and the safety threshold which are corresponding to the current wafer, and outputting them to the pressure control module.

3. The system according to claim 2, wherein
the pressure control module generates the driving pressure signal for the current wafer based on the driving pressure and the safety threshold which are corresponding to the current wafer, such that the lifting pressure output by the wafer lifting device matches the driving pressure and the safety threshold which are corresponding to the current wafer.

4. The system according to claim 3, wherein
the pressure regulation module feedbacks an actual driving pressure signal to the pressure control module, and the pressure control module performs an abnormality judgment based on the received lifting pressure and the actual driving pressure signal.

5. The system according to claim 2, wherein the information of the wafer comprises: a type of the wafer, a number of use times, a type and thickness of a film, a stress of the wafer, and a current phase of a manufacture process.

6. The system according to claim 2, wherein the driving pressure is related to a type of the wafer, a number of use times, a type and thickness of a film, a stress of the wafer, and a current phase of a manufacture process.

7. The system according to claim 2, wherein the safety threshold is less than a minimum of the driving pressure which causes damage to the wafer.

8. The system according to claim 4, wherein the pressure control module performs the abnormality judgment, comprising:
judging whether a state of the wafer is abnormal based on the received lifting pressure; and
judging whether a pressure is abnormal based on the received actual driving pressure signal.

9. The system according to claim 1, wherein the pressure control module comprises:
an amplification unit configured to amplify the received lifting pressure; and
a comparison unit configured to compare the amplified lifting pressure to a safety threshold, and output a state abnormality signal in the case where the amplified lifting pressure is greater than the safety threshold.

10. The system according to claim 9, wherein the pressure control module further comprises:
an energy supply unit configured to provide electric energy for the pressure detection module and the pressure regulation module;
a control unit configured to control the pressure regulation module;
an information transmission-reception unit configured to receive and send data from and to an apparatus master control module via a communication conversion module; and
a data storage unit configured to store data.

11. The system according to claim 10, wherein the communication conversion module is configured for communication conversion between different devices and the pressure control module.

12. A pressure drive method employing the system according to claim 1, the pressure drive method comprising the steps of:
detecting the lifting pressure of the wafer lifting device; and
generating the driving pressure signal for the current wafer based on the received lifting pressure, and regulating the driving pressure for the wafer lifting device based on the driving pressure signal, and then correcting the lifting pressure output by the wafer lifting device.

13. The pressure drive method for the system according to claim 12, wherein a precision control is provided by using cloud data, and the cloud data comprises the driving pressure and a safety threshold which are corresponding to the current wafer.

14. The pressure drive method for the system according to claim 13, further comprising: generating the driving pressure signal for the current wafer based on the driving pressure and the safety threshold which are corresponding to the current wafer, such that the lifting pressure output by the wafer lifting device matches the driving pressure and the safety threshold which are corresponding to the current wafer.

15. The pressure drive method for the system according to claim 14, wherein an abnormality judgment is performed based on the received lifting pressure and an actual driving pressure signal.

16. The pressure drive method for the system according to claim 15, wherein the abnormality judgment comprises:
judging whether a state of the wafer is abnormal based on the received lifting pressure; and
judging whether a pressure is abnormal based on the received actual driving pressure signal.

17. A semiconductor manufacture apparatus, comprising the wafer lifting device, an electrostatic adsorption device, and the pressure drive system according to claim 1, wherein
the electrostatic adsorption device, on which a wafer is placed, is configured to generate an adsorption force to adsorb the wafer during a manufacture process;
the wafer lifting device is located underneath the electrostatic adsorption device and comprises a lift pin, and when the manufacture process ends, the wafer lifting device generates the lifting pressure to lift the wafer by the lift pin from the electrostatic adsorption device; and
the pressure drive system is connected to the wafer lifting device and configured to detect the lifting pressure of the wafer lifting device and generate the driving pressure signal for the current wafer based on the lifting pressure, so as to regulate the driving pressure for the wafer lifting device.

18. The apparatus according to claim 17, wherein the wafer lifting device comprises a pneumatic lifting device.
